(19) United States
(12) Patent Application Publication
(10) Pub. No.: US 2026/0110862 A1
(43) Pub. Date: Apr. 23, 2026

(54) OPTICALLY ACCESSIBLE CIRCUIT PACKAGE HAVING BACKSIDE FIBER ATTACHMENT

(71) Applicant: Celestial AI Inc., Santa Clara, CA (US)

(72) Inventors: Ankur Aggarwal, Pleasanton, CA (US); Subal Sahni, La Jolla, CA (US); Suresh Venkata Pothukuchi, Chandler, AZ (US); Anmol Rathi, San Jose, CA (US)

(21) Appl. No.: 19/096,705

(22) Filed: Mar. 31, 2025

Related U.S. Application Data
(60) Provisional application No. 63/709,197, filed on Oct. 18, 2024.

(51) Int. Cl. G02B 6/43; G02B 6/34; G02B 6/42; H01L 21/56; H01L 23/00; H01L 23/15; H01L 23/31; H01L 23/373; H01L 23/538; H01L 25/16

(52) U.S. Cl. CPC G02B 6/43; G02B 6/34; G02B 6/4204; H10W 70/611; H10W 70/635; H10W 90/00; H10W 40/258; H10W 70/692; H10W 72/01257; H10W 72/072; H10W 74/01; H10W 74/10; H10W 90/722

(57) ABSTRACT

A circuit package includes a photonic integrated circuit (PIC) and four electronic integrated circuits (EIC) electrically connected to and physically overlapping a first surface of the PIC. An optical interface for coupling optical signals into and/or out of the PIC is coupled to a substrate that is attached to a second surface of the PIC opposite the first surface of the PIC. Each EIC includes an analog-mixed signal (AMS) block located at or near a geometric center of the respective EIC. The PIC includes four active regions located at respective corners of the PIC. Each active region of the PIC is coupled to the respective AMS block.

### CROSS-REFERENCE TO RELATED APPLICATIONS

This application claims priority to U.S. Provisional Patent Application No. 63/709,197, entitled “OPTICALLY ACCESSIBLE CIRCUIT PACKAGE WITH CO-PACKAGED OPTICS HAVING BACKSIDE FIBER ATTACHMENT”, filed on Oct. 18, 2024, the entirety of which is incorporated herein by reference.

### BACKGROUND

The subject matter discussed in this section should not be assumed to be prior art merely as a result of inclusion in this section. Similarly, any problems mentioned in this section or associated with subject matter provided as background should not be construed as an admission of prior art.

Integrated circuits (ICs) with processors, especially those for executing artificial intelligence and machine learning functions, move large amounts of data among one or more processor ICs and one or more memory ICs. Chiplets may aid in the interconnection of processor dies, memory dies, and other circuits to increase the bandwidth and decrease latency and power dissipated in the process. In the event that these interconnections utilize optical elements, maintaining optical pathways through an electronic integrated circuit (EIC) of a circuit package can become a challenge and present difficulties, particularly in manufacturing and implementing IC architectures.

### SUMMARY

Examples of the present application provide a chip package with a photonic integrated circuit (PIC) and a plurality of EICs bonded on the PIC. The technical solution is as follows.

One aspect of the present disclosure features a circuit package, including: a substrate including a transparent region positioned to provide an optical path through the substrate from a first surface of the substrate to a second surface of the substrate opposite to the first surface of the substrate. The circuit package includes a photonic integrated circuit (PIC) attached to the first surface of the substrate, the PIC including: four active regions spaced apart from each other, each active region including at least one optical modulator and at least one photodiode; an optical interface adjacent to the transparent region of the substrate; and a plurality of photonic paths connecting the optical interface to the four active regions, each of the plurality of photonic paths including one or more waveguides. The circuit package includes a fiber array unit (FAU) attached to the second surface of the substrate, the FAU being configured to direct optical signals to and receive optical signals from the optical interface through the transparent region of the substrate. The circuit package includes four electronic integrated circuits (EICs) each attached to the first surface of the PIC, each EIC including an analog-mixed signal (AMS) block electrically coupled to a respective one of the four active regions of the PIC via electrical contacts on the first surface of the PIC. For each of the EICs, the AMS block is located 2 mm or more from a nearest edge of the EIC.

In some implementations, each of the four active regions of the PIC is located at or near a respective edge of the PIC.

In some implementations, each of the four active regions of the PIC is located at or near a respective corner of the PIC.

In some implementations, the AMS block of each of the four EICs overlaps the respective active region of the four active regions in the PIC.

In some implementations, each of the four EICs extends beyond corresponding edges of the PIC.

In some implementations, the optical interface is located at or near a geometric center of the PIC.

In some implementations, the FAU is attached at or near a geometric center of the PIC.

In some implementations, the substrate includes at least one of glass or optically transparent silicon.

In some implementations, the substrate includes an interconnection region that includes at least one via, the at least one via is configured to supply power to the EIC, and the transparent region of the substrate is free of vias.

In some implementations, both the transparent region and the interconnection region include glass.

In some implementations, the substrate is a single layer of glass.

In some implementations, the substrate is a multilayer substrate, the transparent region extends through the multilayer substrate, and a layer of the multilayer substrate includes an electrical connection configured to supply power to the EIC and PIC.

In some implementations, the circuit package further includes molding compound at least partially encapsulating the EIC and the PIC.

In some implementations, the AMS block includes at least one driver and at least one transimpedance amplifier (TIA), the at least one driver of the EIC being electrically coupled to the at least one optical modulator of the PIC, and the at least one TIA of the EIC being electrically coupled to the at least one photodiode of the PIC.

In some implementations, the circuit package includes a heat spreader element overlying the EIC.

In some implementations, the heat spreader element directly contacts the EIC.

In some implementations, the optical interface includes an array of grating couplers.

Another aspect of the present disclosure features a method including: providing a substrate including a transparent region; providing a photonic integrated circuit (PIC) including four active regions at a first surface of the PIC, the four active regions spaced apart from each other; and an optical interface at a second surface of the PIC; providing four electronic integrated circuits (EICs) each including an analog-mixed signal (AMS) block that is located 2 mm or more from a nearest edge of the respective EIC; attaching the second surface of the PIC onto a first surface of the substrate such that the optical interface is adjacent to the transparent region of the substrate; flip-chip bonding the four EICs onto the first surface of the PIC such that the AMS block of each EIC overlaps a respective active region of the four active regions of the PIC; and encapsulating the EICs and the PIC onto the substrate.

In some implementations, the method includes attaching a fiber array unit (FAU) to a second surface of the substrate to direct optical signals to and receive optical signals from the optical interface through the transparent region of the substrate.

In some implementations, providing the PIC includes: providing the PIC that is formed using a single reticle.

In some implementations, the substrate includes at least one of glass or optically transparent silicon.

In some implementations, attaching the FAU to the substrate includes attaching the FAU at or near a geometric center of the second surface of the PIC.

In some implementations, the optical interface includes an array of grating couplers.

### BRIEF DESCRIPTION OF THE DRAWINGS

FIG. 1 is a schematic side view of an example of a circuit package having an optically accessible photonic integrated circuit (PIC).

FIG. 2 is a schematic side view of another example of a circuit package having an optically accessible PIC.

FIG. 3A is a schematic side view of yet another example of a circuit package having an optically accessible PIC.

FIG. 3B is a schematic side view of the circuit package of FIG. 3A including a heat spreader element.

FIG. 4 is a schematic side view of still another example of a circuit package.

FIG. 5 is a schematic perspective view of an example of a part of a circuit package.

FIG. 6A is a schematic side view of a further example of a circuit package having a bidirectional optical path through a backside of a PIC and multiple EIC's mounted on a frontside of the PIC.

FIG. 6B is a schematic plan view of the example circuit package shown in FIG. 6A with four EICs on the PIC.

FIG. 6C is a schematic plan view of the example PIC shown in FIGS. 6A and 6B with four active regions positioned at or near respective corners.

FIG. 6D is a schematic plan view of the four EICs shown in FIGS. 6A and 6B each having an analog/mixed-signal (AMS) block positioned at or near a geometric center of the respective EIC.

FIG. 7 is a flow chart of an example of a method of manufacturing a circuit package.

In the drawings, like reference numerals denote like elements.

### DETAILED DESCRIPTION

The present disclosure relates to optically accessible co-packaged optics. Indeed, implementations herein can improve robustness and/or manufacturability of circuit packages with co-packaged optics that facilitate an off-chip bidirectional photonic path. Examples include an optically transparent spacer (also referred to as a “block” or “window”) where optical signals can enter and exit a photonic integrated circuit in a circuit package at a location essentially coplanar with a top edge of the electronic portion, e.g., containing one or more electronic integrated circuits (EICs), of the circuit package. In certain examples, an optical interface is provided on an opposite side of the PIC from the one or more EICs in the package.

Indeed, as will be discussed in further detail below, examples described herein relate to implementations of a circuit package having a bidirectional optical path between optical components in a photonic integrated circuit (PIC) and an optical interface at a top surface of the circuit package. Conventional circuit packages can be difficult and costly to manufacture because the optical interface is attached to a location on the PIC where light enters or exits the PIC. Furthermore, the optical interface must be attached to the PIC with a high level of precision. The less-than-ideal locations on the PIC where light enters or exits make manufacturing difficult.

In general, optically accessible co-packaged optics, such as those described below, can be used in an artificial intelligence (AI) accelerator, a bridge, a chiplet, or any other configuration that can benefit from photonic paths on and off the package or within the package. Examples include electronic integrated circuits (EICs) that share a common PIC interposer and can communicate via intra-chip bidirectional photonic channels. Other examples include circuit packages one or more EICs that communicate with external components via inter-chip bidirectional photonic channels as discussed in further detail herein.

In general, the circuit packages described herein include a PIC that is electrically connected to one or more EICs (e.g., four EICs) where each EIC can, in turn, be electrically connected to other EICs. In some implementations, the four EICs can be placed on a single PIC. The PIC facilitates optical transfer of data between EICs in the same package and/or to and from one or more EICs in other circuit packages. In general, the EICs can include a memory device, a computing device, a storage device, or a combination thereof (examples include, but are not limited to, a random-access memory (RAM) device (such as a static RAM (SRAM) device, a magnetic RAM (MRAM) device, a resistive RAM (RRAM) device, or a conductive-bridging or a conductive-bridging RAM (CBRAM) device), a logic device (e.g., an AND, OR, NANO, NOR, or EXOR gate), a NANO flash memory, a solid state drive (SSD) memory, a NOR flash memory, a CMOS memory, a thin film transistor-based memory, a phase-change memory (PCM), a storage class memory (SCM), a magneto-resistive memory (MRAM), a resistive RAM. a DRAM, a high bandwidth memory (HBM), a DOR-based DRAM, a DIMM memory, a CPU, a GPU, an MPU, a tensor engine, a load/store unit (LDSU), a neural compute engine, a dot-product and/or convolution engine, a field programmable gate array (FPGA), an AI accelerator, or any other suitable circuit element. Multiple instances of these devices may be combined on a single die. For example, an EIC can include a memory comprising multiple memory arrays, one or more processors, other logic, communication circuits, and power management functions, and execute instructions stored in the memory array, or otherwise interact with the memory array using the processors on the EIC. Depending on the EICs connected (directly or indirectly) to the PIC, the packages described here can be used for a compute node or a memory node in a distributed data processing environment.

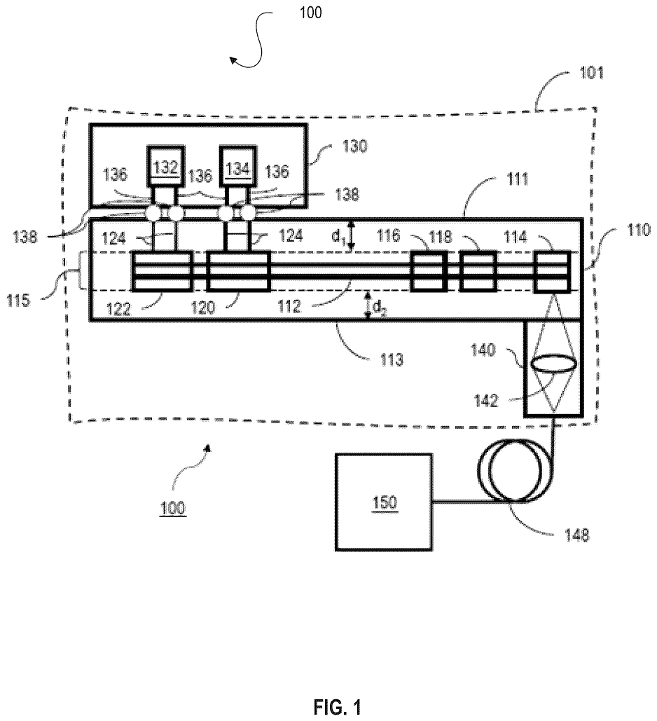

FIG. 1 illustrates a system 100 that includes a first package 101 with co-packaged optics that is optically connected to another package 150 by an optical fiber 148 (or bundle of fibers). The package 101 includes a PIC 110, and EIC 130, and an optical interface 140. The EIC 130 is attached to and overlaps with a top surface 111 of the PIC 110, while the optical interface 140 is attached to and overlaps with a bottom surface 113.

The PIC 110 includes an optical region 115, e.g., composed of one or more patterned layers, that includes waveguides 112, one or more grating couplers 114, one or more demultiplexers 118, one or more multiplexers 116, one or more modulators 120, and a one or more photodiodes 122. The PIC 110 also includes non-optical regions above and below the optical region 115. In general, each of the non-optical regions can include one or more patterned layers of dielectric, semiconductor, and/or electrically conducting (e.g., metal) layers, constituting electrical interconnects (e.g., composed of vias and/or metal traces) for example. The electrical interconnects can traverse the optical region 115 too, providing electrical connections between the bottom and top of the PIC 110.

The thickness of the non-optical regions of the PIC 110 are denoted d₁ and d₂, corresponding to the non-optical region above and below the optical region 115, respectively. In general, the thickness of these regions is selected to provide the PIC 110 with sufficient mechanical integrity and electrical functionality while being relatively thin to provide relatively short electrical paths between the top and bottom surfaces and a relatively short optical path from the bottom surface 113 to the optical region 115. In general, d₁ and d₂ can be similar in thickness or their thickness can vary. In some examples, d₁ and/or d₂ is in a range from 10 mm to 1,000 mm (e.g., 20 mm or more, 50 mm or more, 100 mm or more, 200 mm or more, such as 800 mm or less, 500 mm or less, 300 mm or less).

The EIC 130 includes one or more TIAs 132 and one or more drivers 134. Each TIA 132 is electrically connected to a corresponding photodiode 122 via electrical interconnects 136 in the EIC 130, which connect the TIA 132 and driver 134 to interconnects 138 (e.g., copper pillars), and via electrical interconnects 124 in the PIC 110, which connect the photodiode 122 and modulator 120 to the interconnects 138.

Generally, each photodiode 122 and each modulator 120 have two electrical connections —one to the cathode and one to the anode. The interconnects 138 form a physical connection between the bottom surface of the EIC 130 and the top surface 111 of the PIC 110.

The interconnects 138 can include a bondpad pattern located over modulator 120 and photodiode 122 that matches a bondpad pattern on the EIC 130 located under drivers 134 and TIAs 132 or is otherwise configured to form an electrical interconnection between the respective components.

Two or more bondpads of the bondpad pattern on the EIC 130 are physically and electrically coupled with two or more bondpads of the bondpad pattern on the PIC 110. The distance between the lower surface of the EIC 130 and the top surface of the PIC 110 is typically in the range of 100-400 microns.

In one or more implementations, the interconnects 138 connecting the dies (e.g., the EIC 130) to the top surface of the PIC 110 are 1-400 microns. In addition, the interconnects may be implemented using a variety of structures including, by way of example, copper pillars, solder connections, pads (e.g., bondpads), bump attachments, vias, or any variety of means by which the dies may be coupled to the PIC.

In FIG. 1, an interconnect 138 is shown as making a coupling (or abutted coupling) between elements in the AMS parts of the dies and the corresponding elements in the PIC 110. In one or more implementations, the interconnect is a copper pillar no longer than 2 millimeters. In one or more implementations, the copper pillar can be less than 2 millimeters and, in some instances, less than 400 microns. In other implementations, the electrical interconnects can be solder bumps formed of a material such as tin, silver, or copper. If solder bumps are used for the interconnects, then the solder bumps may be flip-chip bumps. In other implementations, the interconnects may be elements of a ball-grid array (BGA), pins of a pin grid array (PGA), elements of a land grid array (LGA), or another type of interconnect. In each of these examples, the interconnects can be less than 2 millimeters and, in some examples, from 1-400 microns.

In general, the interconnects have drivers (DRVs) or transimpedance amplifiers (TIAs) at one end and optical modulators (MODs) or photodetectors (PDs) at the other end of the PIC 110. For example, in one or more implementations, the interconnects may physically couple with, and allow electrical signals to pass between, pads of the dies and pads of the optical substrate and/or the PIC 110. For instance, an interconnect between a driver and a modulator allows the driver to provide an electrical signal that drives the modulator. In another instance, an interconnect between a transimpedance amplifier (TIA) and a photodetector (e.g., a photodiode) allows the transimpedance amplifier to receive an electrical signal from the photodetector.

The interconnects 138 may not have a uniform size, shape, or pitch. A finer pitch of interconnects may be desirable to allow a denser communication pathway between elements coupled to the PIC 110. In one or more implementations, one or more interconnects have minimal lateral displacement. For example, an interconnect is a copper pillar that is straight up and down, perpendicular to the face of a EIC and the PIC 110 (e.g., between 1-400 microns in length. This allows the transceiver portions in the AMS block (e.g., DRV and TIA) to be directly stacked at one end of the interconnect above its respective transceiver portion in the PIC (EAM and PD) at the other end of the interconnect. In some implementations, the DRV and TIA and EAM and PD can be slightly offset from the copper pillar to reduce parasitics and still enable a sub-400-micron gap (interconnect length) between heat-producing elements in the EIC/AMS and passive elements in the PIC.

The optical interface 140 (e.g., a FAU) includes optics 142 (e.g., one or more lenses) which direct light from the optical fiber 148 to the grating coupler 114 and/or direct light from the grating coupler 114 to the optical fiber 148. The optical interface 140 is attached to the bottom surface 113 of the PIC 110, through which light is coupled into and out of the PIC. The optical interface 140 can be attached using an optical adhesive or some other form of attachment that provides a clear optical path between the optical interface 140 and the PIC 110.

In some implementations, The optical interface 140 can include a variety of mechanisms of providing an interface between the fiber(s) and PIC 110, for example, an edge coupler; a grating coupler (GC), a graded index (GRIN) lens coupler, a fiber Bragg grating (FBG) coupler, a micro-lens array (MLA) coupler, an evanescent wave (EW) coupler, an adiabatic coupler, a wavelength division multiplexing (WDM) coupler, a prism coupler, a butt coupler, an end-fire coupler, and a V-groove coupler.

The package 101 can also include molding compound used to fill spaces between the PIC 110 and EIC 130, and elsewhere.

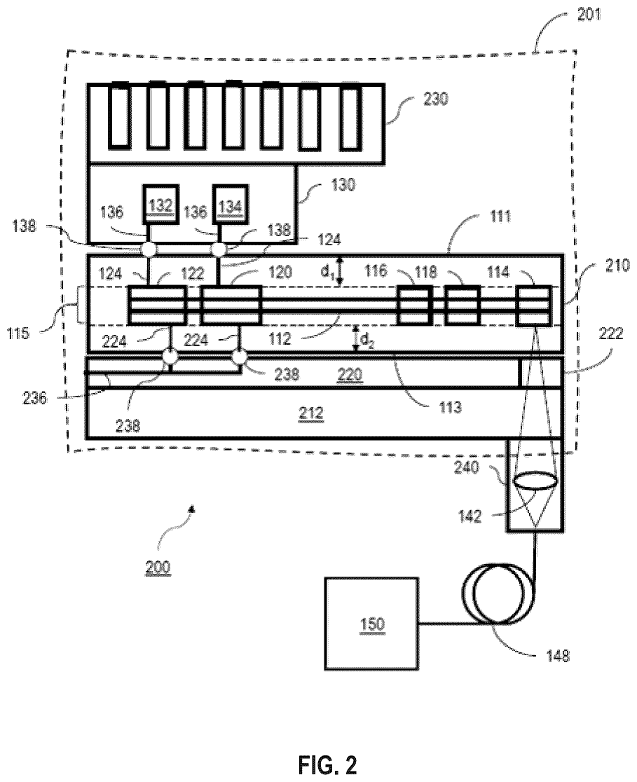

While in PIC 110, both the anode and cathode of the photodiode 122 and modulator 120 are electrically connected to the EIC, other arrangements are possible. For example, referring to FIG. 2, in a further example system 200, a package 201 includes a PIC 210 that has electrical interconnects 224 that connect one electrode (e.g., the cathode or the anode) from each of the photodiode and modulator to the bottom surface 113 of the PIC 210. The other electrode (e.g., the anode or the cathode) is electrically connected to the EIC 130.

Furthermore, while the optical interface shown in package 101 is attached directly to the bottom surface 113 of the PIC, in certain examples, additional components can make up the optical path between the optical interface and the PIC. For example, package 201 includes a substrate 212 and a RDL 220 between the optical interface 240 and the PIC 210. The RDL 220 includes electrical interconnects 236 that connect to copper pillars 238, which provide electrical connections to electrical conduits 224 in the PIC 210. In some examples, electrical interconnects 236 are grounded.

Both the substrate 212 and the RDL 220 include an optically transparent region in the optical path between the optical interface 240 and the bottom surface 113 of the PIC 210 so that light can be transmitted between the PIC and the optical interface. In some cases, either or both of the RDL 220 and the substrate 212 are at least partially formed from an optically transparent material (e.g., a glass or silicon). As shown, substrate 212 is completely composed of an optically transparent material while RDL 220 is partially composed of a transparent portion 222 aligned in the optical path. In general, the optically transparent region is transparent to light at the operative wavelength(s) of the PIC 210 and other optical components. In some examples, the operative wavelengths are in a range from 1,500 nm to 1,600 nm (e.g., in the band of the spectrum referred to as the C-band and/or L-band).

By positioning the EIC on the opposite surface of the PIC from the optical interface, it is possible to include other components that overlap the top surface 111 of the PIC in regions that would otherwise be occupied by the optical interface. For examples, package 201 also includes a heat sink 230 mounted to the top surface of the EIC 130. The heat sink 230 extends over a portion of the surface 111 beyond the edge of the EIC 130. The heat sink 230 is attached to the EIC 130 in a manner that allows efficient heat transfer from the EIC to the heat sink. For example, a thermal interface material, such as a thermal paste, can be used to facilitate this connection.

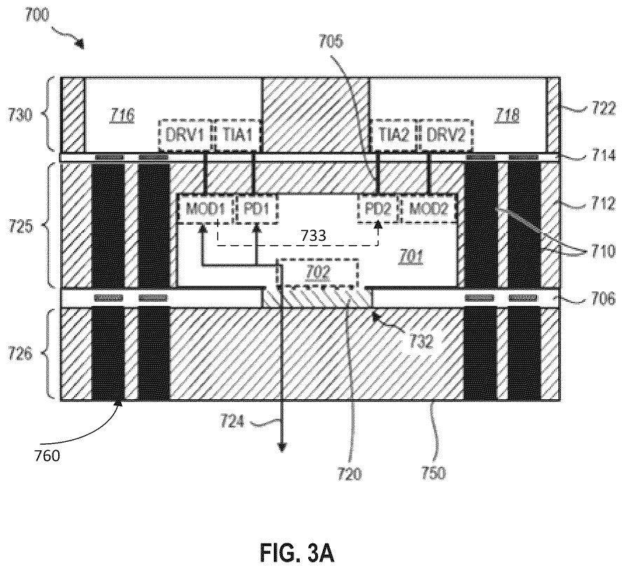

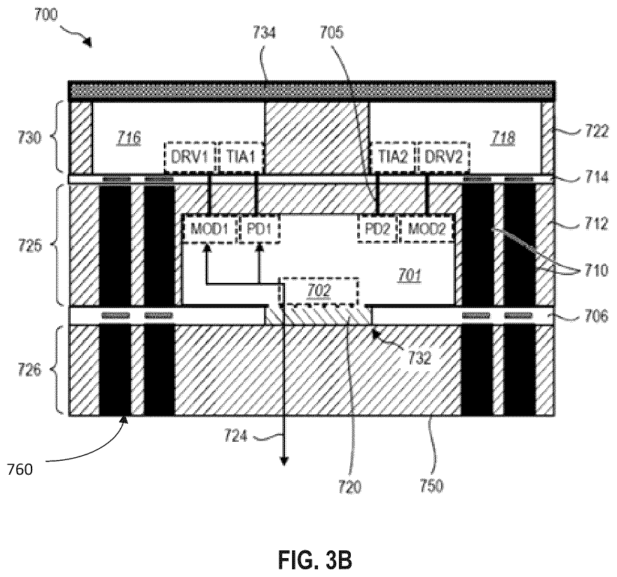

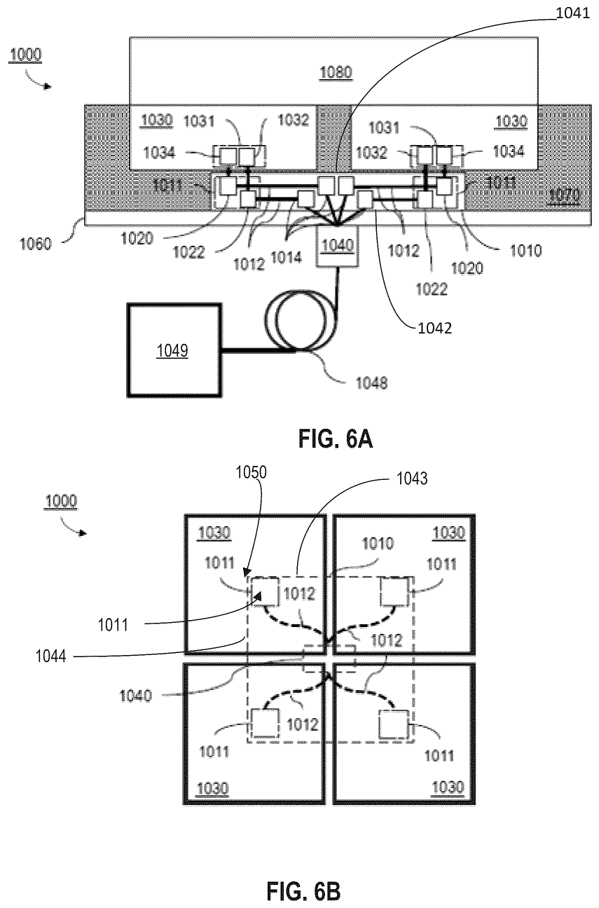

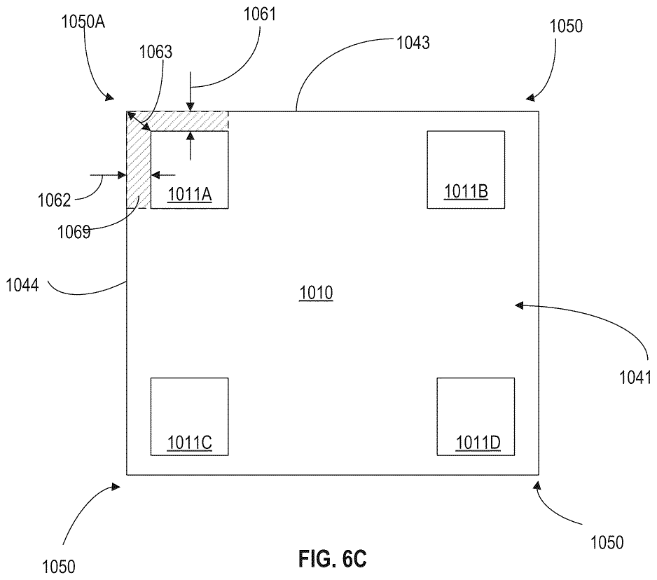

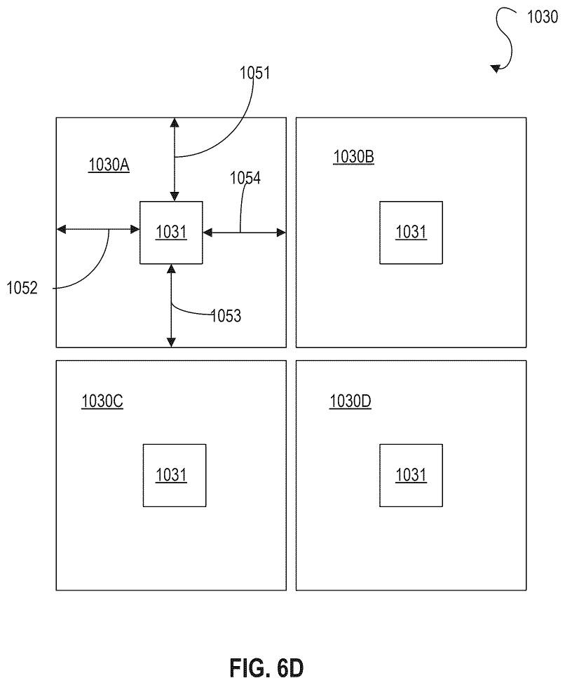

Turning now to the next set of figures, FIGS. 3A, 3B, 4, 5, 6A and 6B illustrate a series of further example implementations of a circuit package that includes an optical path for sending and receiving data signals to and from an external device or devices through a side of PIC opposite of one or more electronic integrated circuits (EICs). Specifically, FIGS. 6A-6B illustrated implementations with four EICs on a single PIC.

Referring to FIG. 3A, an example circuit package 700 includes a PIC 701 with modulators (MOD1 and MOD2) and the photodetectors (PD1 and PD2) (e.g., photodiodes), a grating coupler interface portion 702 (with one or more grating couplers (GCs), interconnects 705, a first redistribution layer 706, vias 710, a molding compound 712, a second redistribution layer 714, a first EIC 716 with a driver (DRV1) and a transimpedance amplifier (TIA1), a second EIC 718 with a driver (DRV2) and a transimpedance amplifier (TIA2), and a molding compound 722, which respectively correspond to the PIC 701 with modulators (MOD1 and MOD2) and the photodetectors (PD1 and PD2), the grating coupler interface portion 702, the interconnects 705, the first redistribution layer 706, the vias 710, the molding compound 712, the second redistribution layer 714, the first EIC 716, the second EIC 718, and the molding compound 722.

Modulator MOD1 modulates the light it receives from the grating coupler interface portion 702 with information from driver DRV1. In some implementations, the modulator MOD1 transmits the modulated light to photodetector PD2 (e.g., photodiode) via photonic path 733. Photodetector PD2 converts the received modulated light to an electrical signal for the second EIC 718. Jointly with a serializer (not shown) in the first EIC 716, the driver DRV1, transimpedance amplifier TIA2, and a deserializer (not shown) in the second EIC 718, modulator MOD1, photonic path 733, and photodetector PD2 form a data channel from the first EIC 716 to the second EIC 718.

Similarly, although optical paths are not depicted in FIG. 3A, modulator MOD2 modulates the light it receives from the grating coupler interface portion 702 with information from driver DRV2. In some implementations, the modulator MOD2 transmits the modulated light to photodetector PD1. Photodetector PD1 converts the received light to an electrical signal for the first EIC 716. Jointly with a serializer (not shown) in the second EIC 718, the driver DRV2, transimpedance amplifier TIA1, and a deserializer (not shown) in the first EIC 716, modulator MOD2, and photodetector PD1 form a data channel from the second EIC 718 to the first EIC 716.

The circuit package 700 includes an optically transparent block 720 below the PIC 701 and a base layer 726 that is optically transparent. Additionally, the grating coupler interface portion 702 within the PIC 701 is located on the bottom side of the PIC 701. FIG. 3A also includes labels that indicate a PIC element layer 725 (including the PIC 701) and an upper layer 730 (including the first EIC 716 and the second EIC 718).

As mentioned, the circuit package 700 includes the PIC 701. As shown, the PIC 701 is placed on top of the first redistribution layer 706, which may be positioned over the base layer 726. Features of the first redistribution layer 706 and the base layer 726 will be discussed in further detail below.

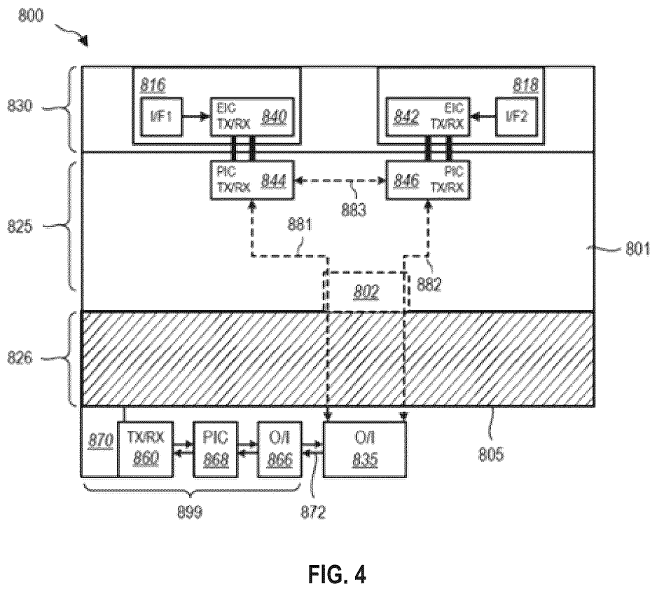

In various implementations, the circuit package 700 may include a portion of one or more of the packages described above. For example, in some of these implementations, the optical interface is placed on an optical substrate and is located on the opposite side of the optical substrate as the first EIC and/or the second EIC (instead of being on the same side as one or both dies as shown in FIG. 3, FIG. 4). In various instances, the optical interface is located on the opposite side of the PIC as the first EIC and/or the second EIC, e.g., as illustrated in FIG. 1 above.

As shown, FIG. 3A includes a PIC element layer 725, which includes at least the PIC 701, the vias 710 (e.g., conductive pillars), and the molding compound 712. The first redistribution layer 706 may be positioned on a first surface (e.g., a bottom or lower surface) of the PIC element layer 725 and vertically between the PIC element layer 725 and the base layer 726. The PIC element layer 725 may be placed below the second redistribution layer 714 where the second redistribution layer 714 is positioned on a second surface (e.g., a top or upper surface opposite the first surface) of the PIC element layer 725 and vertically between the PIC element layer 725 and the upper layer 730. The PIC element layer 725 may be vertically between and may directly contact each of the first redistribution layer 706 and the second redistribution layer 714. The PIC element layer 725 (and the PIC 701) may be vertically between base layer 726 and the first EIC 716 and/or the second EIC 718. In some implementations, the base layer 726 is spaced from the first EIC 716 and the second EIC 718 by the PIC element layer 725 including the PIC 701.

As further shown, the circuit package 700 includes the upper layer 730 above the PIC element layer 725, which includes the first EIC 716 and the second EIC 718. The first EIC 716 and the second EIC 718 may include similar or different types of hardware. In one or more implementations, the first EIC 716 refers to an application-specific integrated circuit (ASIC) chip having been programmed, customized, or otherwise configured for a particular use. The first EIC 716 may also refer to other types of EIC (e.g., electrical EIC components). The second EIC 718 may refer to a similar or different type of EIC as the first EIC 716. For example, in one or more implementations, the second EIC 718 refers to a high bandwidth memory (HBM) hardware, a CPU, a GPU, a tensor engine, a neural compute engine, or an AI accelerator. Other implementations may include other types of hardware. In one or more implementations, one or both of the EIC components are electronic EIC components. Indeed, any of the first EIC 716 or the second EIC 718 may refer to any of the example types of EIC provided above. Other implementations may include additional EIC components.

In the implementation described in FIG. 3A, the base layer 726 refers specifically to an optically transparent base layer. In one or more implementations, this base layer 726 is an optically transparent glass substrate such that an optical path 724 is maintained through the bottom surface of the circuit package 700.

As shown in FIG. 3A, due to the optically transparent nature of the base layer 726, the optical path 724 is maintained between the bottom surface of the PIC 701, an optically transparent block 720 in the first redistribution layer 706, and the base layer 726. The base layer 726 may include one or more glasses, such as silicate glass, silica glass, quartz glass, optically transparent silicon, borosilicate glass (BSG), phosphosilicate glass (PSG), borophosphosilicate glass (BPSG), fluoroborosilicate glass, zinc oxy fluoro borate glass (ZnO—ZnF₂—B₂O₃ glass), another optically transparent material, or combinations thereof. For example, in some implementations, the base layer 726 includes glass. In some implementations, the base layer 726 includes optically transparent silicon. In some implementations, the base layer 726 includes a combination of glass and optically transparent silicon.

In one or more implementations, the base layer 726 is optically transparent across the entire layer of the base layer 726. In some implementations, the base layer 726 includes a uniform (e.g., an integral, unitary body). Alternatively, in one or more implementations, the base layer 726 has multiple regions (e.g., a first and a second region). A first region may refer to a region in which an optical signal is carried from an optical transmitter, waveguide, GC, through the first region and to the lower surface of the base layer 726, where it can be optically coupled to an optical interface such as a fiber array unit (FAU) that attaches to a fiber and carries the optical signal elsewhere (not shown).

The optical signal may also be carried from a transmitter elsewhere (not shown) through a fiber that reaches an optical interface at the bottom surface of the base layer 726, through the first region of the optically transparent block 720, through the optically transparent block 720, and to the grating coupler interface portion 702 of the grating coupler interface portion 702 (e.g., following the optical path 724 from outside of the circuit package 700 to the PIC 701).

In various implementations, the base layer 726 is selectively transparent at a location of the base layer 726 positioned beneath a portion or all of the grating coupler interface portion 702 and/or the PIC 701 (e.g., the first region of the base layer 726). In some implementations, a horizontal dimension (e.g., left and right and in and out of the page in the view of FIG. 3A) of the base layer 726 is the same as (e.g., substantially the same as) a horizontal dimension of the PIC 701. In some implementations, the horizontal dimension (e.g., at least one horizontal dimension) of the base layer 726 is greater than the horizontal dimension of the PIC 701 in the same horizontal direction.

In one or more implementations, the base layer 726 includes vias and other connections through which electrical signals may pass to other layers of the circuit package 700 (e.g., via traversing the first redistribution layer 706) and internal or external elements of a circuit package on which the circuit package 700 is implemented). In some instances, the vias and other connection elements are located in a second region of the base layer 726 that is different from the region through which the optical signal is carried (e.g., a first region).

In one or more implementations, the components of the circuit package 700 are manufactured over a top surface of the base layer 726. In other implementations, the base layer 726 may be added (e.g., coupled to the first redistribution layer 706) after manufacturing some or all of the circuit package 700. For example, in one or more implementations, a carrier layer or base (e.g., a carrier substrate) is removed and replaced with the base layer 726. This may be performed in a similar manner in which the circuit package 700 would be connected to a circuit package.

As noted above, the circuit package 700 may include the first redistribution layer 706 positioned below the PIC element layer 725. The first redistribution layer 706 (and other redistribution layers described herein, such as the second redistribution layer 714) may refer to a layer having a variety of thicknesses, and which includes one or more input/output (I/O) pads that provide availability of electrical elements of the circuit package to other areas of a chip or circuit package on which the circuit package is to be deposited. The redistribution layers (e.g., the first redistribution layer 706 and the second redistribution layer 714) may include wiring, interconnects, and other components that enable components of the circuit package 700 to be electrically coupled to components of one or more additional electronic packages. In some implementations, the redistribution layer 706 can be configured to supply power to the EICs and PIC.

In addition, as shown in FIG. 3A, the first redistribution layer 706 includes an optical opening 732. The optical opening 732 may be printed or cut out of a section of the first redistribution layer 706 to avoid breaking the optical path 724 between a bottom surface 750 of the circuit package 700 and the PIC 701.

In various implementations, the optical opening 732 of the first redistribution layer 706 may be substantially aligned with the PIC 701. For example, the optical opening 732 may be horizontally aligned (e.g., in the left and right direction and in and out of the page in the view illustrated in FIG. 3A) with the grating coupler interface portion 702 of the PIC 701. In some such implementations, the PIC 701 may vertically overlie or overlap the optical opening 732 and the optical opening 732 may be located within horizontal boundaries of the grating coupler interface portion 702 of the PIC 701.

In one or more implementations, the size of the optical opening 732 within the first redistribution layer 706 may be smaller than the size of the grating coupler interface portion 702 and/or the PIC 701 such that only a portion of the PIC 701 is exposed in order to maximize an area of the first redistribution layer 706 through which vias and electrical connections (e.g., vias 710) can be routed between layers of the circuit package 700. Alternatively, the size of the optical opening 732 within the first redistribution layer 706 can be the same size or larger than the PIC 701 to simply provide a reliable optical path between the bottom surface of the circuit package 700 and the PIC 701.

As shown, the first redistribution layer 706 includes an optically transparent block 720 between the base layer 726 and the PIC 701. In some implementations, the optically transparent block 720 is a gap or a separate element located vertically between the base layer 726 and the PIC element layer 725. In some implementations, the optically transparent block 720 is integrated with the base layer 726. For example, the base layer 726 extends into the optical opening 732 to make up the optically transparent block 720. In some instances, outer portions of the base layer 726 are ground down and replaced with other materials and components, leaving the base layer 726 to include the optically transparent block 720, which protrudes and extends up from other portions of the base layer 726 to the PIC 701. In some implementations, the first region of the base layer 726 extends from the PIC 701 to the bottom surface 750 while the second region does not extend up as far and is topped with the first redistribution layer 706. In these instances, the top of the first redistribution layer 706 may be coplanar with the top of the first region of the base layer 726.

The optically transparent block 720 may be formed of and include an optically transparent material, such as one or more of the materials described above with reference to the base layer 726. In some implementations, the optically transparent block 720 includes the same material as the base layer 726. In some implementations, the optically transparent block 720 is monolithic with the base layer 726. In other implementations, the optically transparent block 720 includes a different material than the base layer 726. In other implementations, the circuit package 700 does not include the optically transparent block 720. In some implementations, the base layer 726 includes a portion vertically extending into the optical opening 732. In implementations without the optically transparent block 720, the optical path 724 similarly travels from the PIC 701 to the base layer 726 and out the bottom of the circuit package 700.

As mentioned above, the implementation in FIG. 3A differs from previous implementations in that the optical path 724 is maintained between the bottom surface 750 of the circuit package 700 (e.g., from the bottom surface of the base layer 726) and the PIC 701. The optical path 724 may represent one of multiple paths, such as a path to other components (e.g., PD2 and MOD2) in the PIC 701. Additionally, while not shown the PIC 701 may include optical paths and/or waveguides between the components, in a similar manner as described in some of the above figures.

In one or more implementations, the circuit package 700 includes multiple optical paths to the PIC 701. For example, while not explicitly illustrated in the figures, an implementation of the circuit package 700 may include a first optical path between the top surface of the circuit package 700 and the PIC 701 (e.g., as shown in FIG. 2) in addition to a second optical path between the bottom surface 750 of the circuit package 700 and the PIC 701 (e.g., as shown in FIG. 3A).

Also mentioned above, the circuit package 700 shown in FIG. 3A may be created using a similar manufacturing process as discussed above in connection with previous figures. For example, the EIC components (e.g., the first EIC 716 and the second EIC 718), PIC 701, and the vias 710 may be secured within respective layers using one or more molding compounds (e.g., the molding compound 712 and the molding compound 722) that is applied in one or multiple stages. In these implementations, however, the optically transparent blocks between the PIC and the top surface of the circuit package are omitted or filled with the molding compounds.

The molding compounds 712, 722 may be made from a variety of materials having various properties. For example, in one or more implementations, the molding compounds 712, 722 are epoxy molding compounds in a liquid form that secure elements of the circuit package 700 in place and cover certain elements contained within a structure of the circuit package 700. As shown, the molding compound 712 may be located vertically (e.g., in the up and down direction in the view of FIG. 3A) between the first redistribution layer 706 and the second redistribution layer 714. In some implementations, the molding compound 712 is vertically coextensive (e.g., has the same vertical height) as the vias 710. In some implementations, the PIC 701 is located within vertical boundaries defined by an upper surface and a lower surface of the molding compound 712.

The vias 710 may be formed of and include one or more conductive materials. In one or more implementations, the vias 710 include copper pillars extending upwards from the top surface of the first redistribution layer 706. The vias 710 may refer to conductive vias that provide interconnectivity between different layers of an electrical system within which the circuit package 700 is located. In various implementations, the base layer 726 includes similar vias and/or connect to the vias 710. In one or more implementations, the vias 710 vertically span some or all of the PIC element layer 725 and the base layer 726. The vias 710 may be manufactured in any known way so electrical signals (such as power and control signals) can reach the first redistribution layer 706. Features and functionality of the conductive through vias 710 may be similar to the through-substrate vias (TSVs) discussed in U.S. patent application Ser. No. 18/076,196 entitled “THROUGH-SUBSTRATE VIA FORMED USING A PARTIAL PLUG THAT EXTENDS INTO A SUBSTRATE”, the entirety of which is incorporated herein by reference.

In one or more implementations, the vias 710 include bump attach units or other types of electrical interconnects, which generally bridge the gap between electrical portions of a photonic transceiver located in the electrical layer or in association with an ASIC (e.g., within the upper layer 730 including the first EIC 716 and the second EIC 718) and photonic portions of the transceiver (e.g., including a modulator and photodetector) which reside in the PIC 701.

In addition, it will be understood that while FIG. 3A illustrates four of the vias 710, the circuit package 700 may include any number of vias deposited over a surface or area of the circuit package 700. Further, while FIG. 3A illustrates a side view showing a single row of vias 710, additional pillars may be placed along additional axes (e.g., y-axis, z-axis) relative to the side view shown and discussed herein.

The example shown in FIG. 3A includes several features that provide benefits in connection with implementations of a circuit package including the PIC 701. For example, by providing the optical path 724 between the bottom surface 750 of the circuit package 700 and the PIC 701, the process of manufacturing the circuit package 700 is greatly simplified. Indeed, because the base layer 726 is a single layer, in various instances, the optical path 724 may be achieved while maintaining a normal or conventional manufacturing process for the rest of the circuit package 700. In addition, by providing the optical path 724 through the bottom surface 750 of the circuit package 700, the PIC element layer 725 and/or other upper layers may be implemented within existing or conventional circuit systems.

Another benefit is discussed in connection with an example implementation shown in FIG. 3B. FIG. 3B expands upon the concepts discussed in FIG. 3A. To illustrate, FIG. 3B includes the circuit package 700 shown and discussed in connection with FIG. 3A. In FIG. 3B, the circuit package 700 also includes a heat spreader element 734 deposited on the top surface of the circuit package 700. The heat spreader element 734 extends over and vertically overlies the first EIC 716, the second EIC 718, and some or all of the molding compound 722.

The heat spreader element 734 provides a mechanism to spread heat that generates or is otherwise emitted from the EIC components and other heat-generating elements on the circuit package 700. In some implementations, the heat spreader element 734 directly contacts the first EIC 716, the second EIC 718, and/or the molding compound 722.

As mentioned above, having the optical path 724 through the bottom of the circuit package 700 enables various benefits. As shown in FIG. 3B, another benefit includes allowing for the heat spreader element 734 to be added to the circuit package 700. In the illustrated implementation, the heat spreader element 734 can be added as a solid piece to dissipate heat without overly complicating the manufacturing process. However, in a few instances, a heat spreader element or set of heat spreader elements may be added to a circuit package that includes an optical path that passes through the top surface of the circuit package. In these instances, the heat spreader element may be arranged in a pattern to avoid obstructing the optical path passing through the top surface.

In various instances, having a single, integral, and/or unitary heat spreader element, as shown that does not include multiple pieces may facilitate a more uniform heat transfer and heat distribution through the heat spreader element 734 compared to a heat spreader element exhibiting a non-uniform composition or structure over the top surface of the upper layer 730, which may include the first EIC 716, the second EIC 718, and the molding compound 722. A substantially uniform heat transfer with the heat spreader element 734 may facilitate improved operations of the first EIC 716 and the second EIC 718 (and other processing elements of a circuit package 700) compared to circuit packages that do not include the heat spreader element 734 or that include non-integral or non-uniform heat spreader elements (e.g., heat spreader elements with an opening for an optical path).

FIG. 3B shows an example of the heat spreader element 734 positioned over the top of the EIC components (e.g., the first EIC 716 and the second EIC 718) and surrounding the EIC elements and is not intended to be limiting to any particular way in which the heat spreader element 734 can be implemented on the circuit package 700. Further, while FIG. 3B illustrates a single instance of the heat spreader element 734, other implementations can have multiple heat spreader elements positioned on different outside surfaces and/or throughout one or more layers of the circuit package 700.

The heat spreader element 734 may be made using a variety of materials with different heat-dissipating characteristics. In one or more implementations, the heat spreader element 734 is an aluminum heat spreader made using one or more slabs of metal (e.g., aluminum metal). Other implementations may use different types of heat-dissipating techniques, such as heatsink(s), or some combination of heat-dissipating elements (e.g., heat spreaders and/or heatsinks). In one or more implementations, the circuit package 700 further includes a fan or other cooling mechanism.

Moving on, FIG. 4 provides an example schematic representation of a circuit package 800 with a PIC 801 according to some implementations. For example, FIG. 4 illustrates an example side view showing a cross-section of a circuit package 800 including one or more similar elements as the schematic diagrams of the packages discussed in the above figures. FIG. 4 illustrates one example implementation of a circuit package 800 or other circuit packages described herein and, it is not intended to limit to the specific elements shown in the side view of the circuit package 800.

More specifically, FIG. 4 illustrates an example implementation of a circuit package 800 within an electrical interconnect configuration having many of the elements of the circuit packages discussed in connection with the examples herein. In one or more implementations, the circuit package 800 includes a PIC element layer 825 including a PIC 801 that is optically accessible. In some instances, the PIC 801 is an optical multi-EIC interconnect bridge (OMIB). The PIC 801 may be an example of one or more of the previous PICs described above.

In the illustrated example, a first EIC 816 and a second EIC 818 are implemented within an upper layer 830 of the circuit package 800. The upper layer 830 may include an electronic integrated circuit (EIC), where the first EIC 816 and the second EIC 818 are a portion of the EIC. The first EIC 816 and the second EIC 818 may include similar features as the corresponding dies discussed above in connection with previous figures.

In some implementations, the first EIC 816 and the second EIC 818 communicate with each other and/or external EIC (e.g., an external package 899) via the PIC 801. For example, the PIC 801 is connected to the first EIC 816 and the second EIC 818 via electrical connections. Additionally, the circuit package 700 provides an optical pathway between the PIC 801 and a bottom surface 805 of the circuit package 800. In some instances, the PIC 801 makes up a portion of a PIC element layer 825, which may correspond to and/or be substantially the same as the PIC element layer 725 of the circuit package 700 shown in FIG. 3A.

In some implementations, the PIC element layer 825 includes one or more conductive pillars (not shown) extending therethrough, as described above with reference to the PIC element layer 725 of FIG. 3A. In some implementations, conductive pillars extend through a molding compound of the PIC element layer 825 and not through the PIC 801.

The circuit package 800 shown in FIG. 4 may refer to an example inter-package connection. In various implementations, the first EIC 816 and the second EIC 818 can communicate with an external device (e.g., a fiber array unit (FAU) or edge coupler) via an optical interface 835.

In various implementations, the first EIC 816 is an example of a first EIC (described above) and includes a first EIC portion 840. The first EIC portion 840 may be an example of the AMS part 716A described above in connection with FIG. 3A that includes a driver (e.g., DRV1) and a transimpedance amplifier (TIA1). The first EIC 816 may further include a EIC interface I/F1 configured to receive an electrical signal from the transimpedance amplifier and output an electrical signal to the driver of the first EIC portion 840. The EIC interface I/F1 may deliver a digital signal carrying information to be transmitted to the driver of the first EIC portion 840, as described above. The driver and the transimpedance amplifier of the first EIC portion 840 may be substantially similar to the driver DRV1 and transimpedance amplifier TIA1 described above with reference to FIG. 3A.

Similarly, in one or more implementations, the second EIC 818 is an example of the second EIC described above in connection with FIG. 3A and may include a second EIC portion 842. The second EIC portion 842 may be an example of the AMS part 718A that includes a driver (e.g., DRV2) and a transimpedance amplified (TIA2). The second EIC 818 may further include a EIC interface I/F2 that receives an electrical signal from the transimpedance amplifier for outputting an electrical signal to the driver of the second EIC portion 842. In some implementations, the EIC interface I/F2 converts a voltage to a digital signal suitable for processing, as described above.

The PIC 801 may include a first PIC portion 844 and a second PIC portion 846 located. The first PIC portion 844 may communicate with (e.g., in optical and electrical communication with) the first EIC portion 840 of the first EIC 816. The second PIC portion 846 may communicate with (e.g., in optical and electrical communication with) the second EIC portion 842 of the second EIC 818. In some instances, the first PIC portion 844 and the second PIC portion 846 may directly or indirectly communicate with each other with one or more bidirectional photonic paths 883 (which may include multiple unidirectional photonic paths).

In some implementations, the first PIC portion 844 includes a modulator (e.g., MOD1) and the photodetector (e.g., PD1) while the second PIC portion 846 includes the modulator (e.g., MOD2) and the photodetector (e.g., PD2), as provided earlier. Thus, the first EIC portion 840 of the first EIC 816 and the first PIC portion 844 may form a photonic transceiver, such as a first photonic transceiver. Similarly, the second EIC portion 842 of the second EIC 818 and the second PIC portion 846 may form a photonic transceiver, such as the second photonic transceiver.

In some implementations, the upper layer 830 directly overlies and contacts the PIC element layer 825. In other implementations, a redistribution layer is between the upper layer 830 and the PIC element layer 825. In these implementations, electrical interconnects may electrically couple components of the upper layer 830 to the PIC element layer 825. For example, via electrical interconnects, the driver of the first EIC portion 840 of the first EIC 816 may be electrically coupled to the modulator of the first PIC portion 844, the transimpedance amplifier of the first EIC portion 840 of the second EIC 818 may be electrically coupled to the photodetector (e.g., a photodiode) of the first PIC portion 844, the driver of the second EIC portion 842 of the second EIC 818 may be electrically coupled to the modulator of the second PIC portion 846, and the transimpedance amplifier of the second EIC portion 842 of the second EIC 818 may be electrically coupled to the photodetector of the second PIC portion 846.

As shown in FIG. 4, components of the first PIC portion 844 and the second PIC portion 846 may be coupled to a coupler interface portion 802 (e.g., a grating coupler (GC)). The coupler interface portion 802 may include a first grating coupler configured to transmit optical signals from the PIC 801 (e.g., from the first PIC portion 844 and/or the second PIC portion 846) to the optical interface 835 and a second grating coupler configured to receive optical signals from the optical interface 835 and transmit the optical signals to the PIC 801 (e.g., to one or both of the first PIC portion 844 and the second PIC portion 846).

The coupler interface portion 802 may be optically coupled to the optical interface 835 (or other external device optical interface) that enables a portion of an optical path through the circuit package 800 from the PIC 801 to the optical interface 835. In one or more implementations, the optical path travels through a base layer 826 of the circuit package 800. The circuit package 800 may include an optical path that may be the same or substantially the same as the optical path 724 described above in connecting with FIG. 3A. To illustrate, the circuit package 800 includes bidirectional photonic paths 881, 882 that represent an optical path.

In some implementations, one or more of the bidirectional photonic paths 881, 882 are horizontally aligned with the optical interface 835 and the coupler interface portion 802 of the PIC 801. In some implementations, the optical interface 835 and the coupler interface portion 802 are horizontally aligned and spaced from one another by the base layer 826.

In various implementations, the base layer 826 is optically transparent and may be the same or substantially the same as the base layer 726 described above in connection with FIG. 3A. In some instances, the base layer 826 may be formed of an optically transparent material, such as one or more of the materials described above (e.g., glass). Other implementations may have different components that directly or otherwise allow optical signals to pass from the optical interface 835 to the PIC 801.

As shown in FIG. 4, the circuit package 800 enables communication between the first EIC 816, the second EIC 818, and/or the PIC 801 and an external package 899 (e.g., memory, CPU, or both). Specifically, the circuit package 800 includes the upper layer 830 including the EIC (e.g., the first EIC 816 and the second EIC 818), the PIC element layer 825 including the PIC 801, the base layer 826, and the optical interface 835.

In some implementations, the circuit package 800 is optically coupled to the external package 899. In various implementations, the external package 899 is the same as the circuit package 800. In various implementations, the external package 899 includes an optical interface 866 in optical communication with the optical interface 835 of the circuit package 800 via fibers 872, a PIC 868 coupled to the optical interface 866, a transceiver 860 coupled to the PIC 868, and EIC 870 coupled to the transceiver 860.

In various implementations, the external package 899 has a receiver coupled to the transmitters of the circuit package 800 (e.g., the first EIC portion 840 and/or the first PIC portion 844). For example, the transceiver 860 of the external package 899 includes a receiver that optically (e.g., photonically) connects with the modulator of the first PIC portion 844 (e.g., the TX) and/or the modulator of the second PIC portion 846, which electronically connects with the first EIC portion 840 and/or second EIC portion 842, respectively. Similarly, in various implementations, the external package 899 has a transmitter coupled to the receivers of the circuit package 800. For example, the transceiver 860 includes a transmitter that optically (e.g., photonically) connects with the photodetector (e.g., a photodiode) of the first PIC portion 844 (e.g., the RX) and/or the photodetector of the second PIC portion 846), which electronically connects with the first EIC portion 840 and/or second EIC portion 842, respectively.

Communication between the external package 899 and the circuit package 800 includes photonic communication via the bidirectional photonic paths 881, 882 of the circuit package 800. In some implementations, the bidirectional photonic paths 881, 882 includes a first set of unidirectional photonic paths in one direction (e.g., from the external package 899) and a second set of unidirectional photonic paths in the opposite direction (e.g., to the external package 899). The unidirectional and/or bidirectional photonic paths may include one or more waveguides through the circuit package 800.

In some implementations, the circuit package 800 includes a redistribution layer between the base layer 826 and the PIC element layer 825, as described above with reference to FIG. 3A, where the first redistribution layer 706 is between the base layer 726 and the PIC element layer 725 of the circuit package 700. Similarly, the circuit package 800 may include another redistribution layer between the upper layer 830 and the PIC element layer 825, as described above. Further, in some implementations, a heat spreader element may directly overlap or overlie (and, in some implementations, directly contact) the upper layer 830, as described above with reference to the heat spreader element 734 in FIG. 3B.

In various implementations, as described above, the PIC 801 may include multiplexers and/or demultiplexers. In some implementations, the first EIC 816 may transmit an optical signal to the optical interface 866 of the external package 899 via a EIC interface I/F1 in the first EIC 816 (e.g., I/F1), a driver in the first EIC portion 840 (e.g., DRV1), a modulator in the first PIC portion 844 (e.g., MOD1), an optional multiplexer MUX (e.g., in case wavelength division multiplexing is desired), the coupler interface portion 802, one or more of the bidirectional photonic paths 881, the base layer 826, the optical interface 835, and the fibers 872.

Conversely, in some instances, the first EIC 816 may receive from optical interface 866 of the external package 899 via the fibers 872, the optical interface 835, one or more of the bidirectional photonic paths 882, the base layer 826, the coupler interface portion 802, an optional demultiplexer DEMUX (e.g., in case wavelength division multiplexing is desired), a first PIC portion 844 (e.g., PD1), a transimpedance amplifier on the first EIC portion 840 (e.g., TIA1), and to the EIC interface I/F1 in the first EIC 816 (e.g., I/F1).

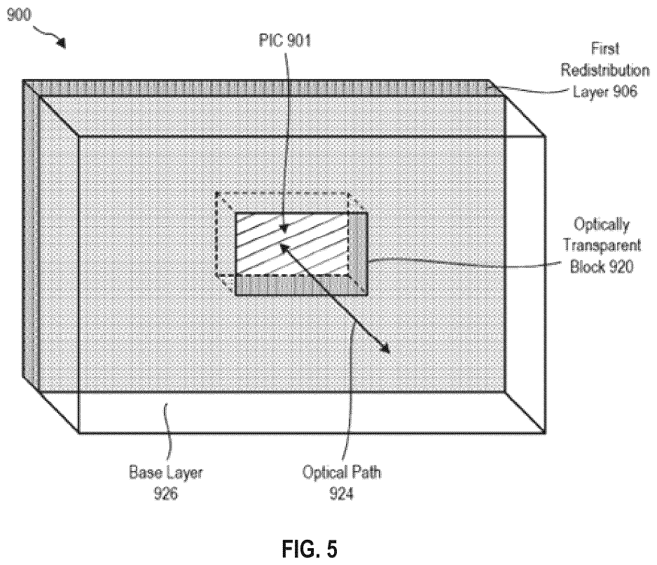

FIG. 5 illustrates an example view of a bottom view of a circuit package according to one or more implementations. As shown in FIG. 5, a circuit package 900 includes a base layer 926, a first redistribution layer 906, an optically transparent block 920, and a PIC 901. Additionally, an optical path 924 connects the PIC 901 to the bottom of the circuit package 900 via the optical path 924, as described above.

The circuit package 900 in FIG. 5 shows the bottom surface of the base layer 926 as a front-facing surface. In various implementations, at least a portion of the base layer 926 of the circuit package 900 is made up of transparent material, such as glass, as described above.

In addition, the circuit package 900 shows the bottom and side surfaces of the first redistribution layer 906, represented with the dotted surfaces. In one or more implementations, the first redistribution layer 906 may be the same or substantially similar to the first redistribution layers described above. The first redistribution layer 906 also includes an opening in a middle region that allows optical access to the PIC 901. In particular, the opening allows the optical path 924 to travel through the base layer 926, through the optically transparent block 920, and into the PIC 901 (only a bottom surface of the PIC 901 is included.

In various implementations, the base layer 926 contacts a first surface of the optically transparent block 920, and an opposite second surface of the optically transparent block 920 contacts the PIC 901. In various implementations, the second surface of the optically transparent block 920 contacts a coupler interface portion with the PIC 901, in the manner described above. Additionally, a fiber array unit (FAU) may attach to the base layer 926 to connect one or more fibers to the circuit package 900. In this way, the optical path 924 can provide one or more bidirectional photonic paths from the PIC 901 to external components.

Referring to FIGS. 6A and 6B, a further example of a package 1000 includes a single PIC 1010 co-packaged with four EICs 1030. A FAU 1040 is attached to a substrate 1060 that is on a backside surface of the PIC 1010, opposite the EICs. At least a portion of the substrate is transparent, providing an optical path through the substrate to the backside of the PIC. The FAU 1040 attaches an optical fiber 1048, forming a bidirectional optical path from another package 1049. The PIC 1010 includes multiple waveguides 1012 that optically connect grating couplers 1014 to active elements (optical modulators 1020 and photodiodes 1022). The active elements are located in active regions 1011 located away from the grating couplers 1014 and underneath a corresponding AMS block 1031 in the EICs 1030. The AMS blocks 1031 each include a TIA 1032 and a driver 1034 (e.g., for each corresponding photodiode 1022 and modulator 1020 in the adjacent active region 1011). The EICs 1030 are flip chip bonded to the top surface of the PIC 1010. A molding compound 1070 at least partially encapsulates the PIC 1010 and the EICs 1030 against the substrate 1060. A heat sink 1080 is thermally coupled (e.g., via a thermal compound) to the top surfaces of the EICs 1030.

As illustrated in FIG. 6A, the grating couplers 1014 are located at or near a geometric center of a second surface 1042 of the PIC 1010. In other words, the grating couplers 1014 are arranged approximately equidistant from the opposite edges of the PIC in both directions. For example, the central grating coupler(s) can be with 2 mm (e.g., 1 mm or less, 0.5 mm or less) from the geometric center of the surface.

Referring now to FIG. 6C, the active regions 1011 are positioned at or near the corners 1050 of the PIC 1010. As such, the four active regions 1011 are approximately equidistant from the grating couplers. The active region 1011 can correspond to the smallest quadrilateral that encompasses all active components (e.g., photodetectors, modulators) in that region. In plan view, an active region 1011 is located at or near two adjoining edges of a first surface 1041 that form the nearest corner. For example, the active region 1011 can be within 2 mm (e.g., 1 mm or less, 0.5 mm or less) from each of adjacent two edges. Here, when an active region 1011 of the PIC 1010 is considered to be located near or at an edge of the PIC 1010, there are typically no active components between the active region 1011 and the respective edge. In examples shown in FIG. 6C, the nearest edges for the first active region 1011A are the edge 1043 and the edge 1044. The spacing distance 1061, 1062 between the first active region 1011A and either edge 1043, 1044 can be 2 mm or less. A region 1069 that is between the first active region 1011A and edges 1043, 1044 are free of active components (e.g., photodetectors, modulators). Additionally, a spacing distance between an active region 1011 and a nearest corner 1050 can be the smaller of a distance from a vertex or from either of two adjoining edges that form the corner. For example, the distance between the first active region 1011A and the nearest corner 1050A can be the smaller of the spacing distance 1063 from the vertex, or the spacing distance 1061, 1062 from edges 1043, 1044.

While FIG. 6C illustrates that edges of active regions 1011 are parallel to the edges of the PIC 1010, in some implementations, edges of the active regions 1011 are not parallel to those of the PIC 1010. In such cases, the spacing distance between the active region 1011 and the edges of PIC 1010 can be a minimum distance between any point on the edges of the active region 1011 and a respective edge of the PIC 1010.

Referring now to FIG. 6D, in plan view, the AMS blocks 1031 are located at or near geometric centers of respective EICs 1030 (e.g., within a distance of 0.5 mm or less, 1 mm or less, or 2 mm or less), away from the edges of the EIC 1030. This means the AMS block 1031 is approximately equidistant from the opposite edges of the respective EIC 1030 in both directions. For example, the distances 1051, 1052, 1053, and 1054 are approximately equal (e.g., differing by no more than 3%, 5%, or 10%). The AMS blocks 1031 can be a chip that is attached onto the substrate of the EIC 1030, or a circuit block directly formed on the substrate of the EIC 1030. When the AMS block 1031 is a circuit block directly formed on the substrate of the EIC 1030, the AMS block 1031 can correspond to the smallest quadrilateral that encompasses all active components (e.g., drivers, TIA) in that region.

Here, when a portion of an integrated circuit (e.g., an AMS block) is considered to be located away from an edge of the die, the nearest part of that portion is typically separated from the edge by another portion of the circuit. For example, in a processor, a processor core can be between the AMS block and the edge of the circuit. Generally, a portion of an integrated circuit that is away from the edge can be physically located 1 mm or more (e.g., 2 mm or more, 3 mm or more, 4 mm or more, 5 mm or more, 6 mm or more, 8 mm or more, 10 mm or more, such as 20 mm or less) from the nearest edge.

Returning to FIGS. 6A and 6B, each AMS blocks 1031 overlaps the respective active region 1011. Each of the EICs 1030 overlaps a corresponding corner of the PIC but extend over the edges of the PIC. Such an arrangement may be advantageous because it allows low latency, high bandwidth connection of multiple EICs to a single PIC having an area smaller than the four EICs. Locating the AMS blocks 1031 centrally in the EICs places the photonic interface symmetrically among the other components of the EIC, facilitating efficient use of components of the EIC. For instance, in examples where the package is part of a compute node and the EICs are multicore processors, arranging the AMS blocks centrally between the cores of each processor can facilitate efficient access to the cores, optically, from other components of a system.

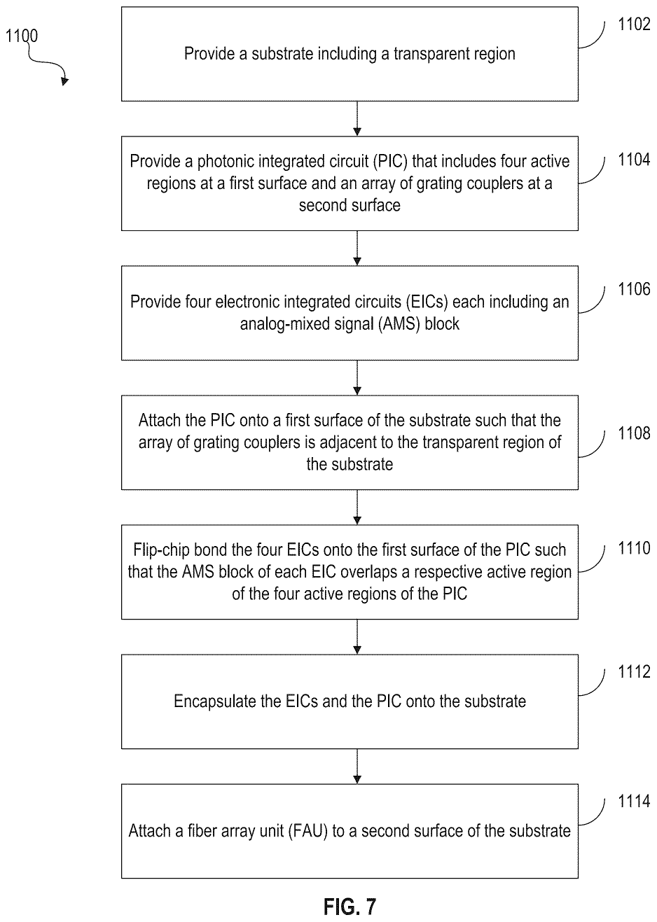

Such configurations may be particularly advantageous where the size the PIC is limited (e.g., by foundry or other manufacturing constraints). Backside attachment of the FAU and central placement of the AMS block (i.e., away from the edges of the EICs) allows EICs to be mounted close together (e.g., separated by spaces smaller than the dimensions of the FAU), enabling a package with multiple EICs and a single PIC. Backside attachment can eliminate the need for additional space for the FAU on the front surface of the PIC, enabling the EICs to cover the entire area or nearly the entire area of the front surface of the PIC. Additionally, as described with greater details below in reference to FIG. 7, the backside attachment allows the use of a single reticle for manufacturing the PIC that supports four EICs, eliminating the need to stitch two or more reticles together and thereby reducing manufacturing cost. Further, as noted above, the central positioning of the AMS blocks in the corresponding EICs can reduce latency and allow high bandwidth connection.

In some implementations, as illustrated in FIG. 6B, the waveguides 1012 have substantial equal length (e.g., with a difference of 5% of less, 10% or less, or 20% or less) extending from the array of grating couplers 1014 to the respective active regions 1011. The waveguides 1012 are arranged in a symmetric configuration.

In some implementations, the substrate 1060 includes an interconnection region that has vias (e.g., vias 710 of FIGS. 3A and 3B) and circuits configured to supply power to the EICs 1030 and the PIC 1010, and the transparent region (e.g., 920 of FIG. 5) of the substrate 1060 is free of vias. In the example implementations where the entire substrate 1060 is made of glass or optically transparent silicon, the vias are formed in the glass or optically transparent silicon.

While FIG. 6A shows that the PIC 1010 is directly in contact with the substrate 1060, the PIC is typically bonded to the substrate through bonding contacts (e.g., solder bumps, micro-bumps, pillars, or bonding pads). The bonding contacts can be surrounded by an optically clear material (e.g., silicone encapsulant, epoxy resin, etc.) to enhance mechanical strength.

FIG. 7 is a flow chart of an example of a method 1100 of manufacturing a circuit package. The circuit package can be the package 1000 of FIGS. 6A-6D.

At step 1102, a substrate is provided that includes a transparent region. The substrate can be the substrate 212 of FIG. 2, the base layer 726 of FIGS. 3A and 3B, the base layer 826 of FIG. 4, the base layer 926 of FIG. 5, or the substrate 1060 of FIGS. 6A and 6B. The substrate includes one or more glasses, such as silicate glass, optically transparent silicon, or combinations thereof. In some implementations, the entire substrate is made of glass or optically transparent silicon. In some other implementations, the substrate includes an optically transparent region, as shown in FIG. 5, while the reminder of the substrate is non-transparent.

At step 1104, a PIC is provided. The PIC has four active regions at a first surface of the PIC, and the four active regions are spaced apart from each other. The PIC further includes an array of grating couplers at a second surface of the PIC. The PIC can be, e.g., the PIC 1010 of FIGS. 6A-6C.

In general, the PICs described herein can be manufactured using standard wafer fabrication processes, including, e.g., photolithographic patterning, etching, ion implantation, etc. Further, in some examples, heterogeneous material platforms and integration processes are used. For example, various active photonic components, such as optical modulators and photodetectors used in the photonic channels, may be implemented using group III-V semiconductor components.

Manufacturing a PIC includes manufacturing a plurality of photonic paths that connect the array of grating couplers to the four active regions. Each photonic path includes one or more waveguides. In some implementations, the PIC is manufactured using a single reticle process, where all the photonic components-such as waveguides, modulators, and detectors-are formed on a single substrate (e.g., silicon, or indium phosphide (InP)). A reticle size (and consequently the size of a single PIC) may be limited by manufacturing capability. In some cases, without the techniques described in the present disclosure, a larger PIC would be needed to support four EICs. Therefore, two or more reticles may be required to form a sufficiently large PIC. In contrast, with the techniques described in the present disclosure (e.g., backside FAU attachment and four active regions located near respective edges or corners of the PIC), the required PIC size for supporting four EICs can be reduced, allowing for the use of a single reticle to fabricate the PIC. This approach may eliminate the need to fabricate two separate PICs on two separated substrates and then bond them together. By forming the substrate using a single reticle, the entire PIC can be patterned and built in a single and seamless process, thereby reducing manufacturing cost. It is to be noted that, here, forming a PIC with a single reticle may refer to that the PIC can be a single and seamless structure rather than an assembly of two separate structures. It is further to be noted that during the manufacturing process of the PIC, multiple reticles can be used at different stages to define patterns for waveguides, detectors and/or modulators.

At step 1106, four EICs are provided. Each EIC includes an AMS block that is located 2 mm or more from a nearest edge of the respective EIC. The EIC can be, e.g., the EIC 1030 of FIGS. 6A, 6B and 6D. The EICs can be manufactured using standard wafer fabrication processes described herein. In some examples, providing a EIC can include integrating one or more high-bandwidth memories (HBM), one or more processors, and an AMS block on a substrate, with the AMS block being positioned at or near the geometric center of the EIC. The AMS blocks are electrically connected to the one or more HBMs or the one or more processors through interconnects in the substrate. In some examples, the processors are disposed equidistant from the AMS block to reduce latency. It is to be noted the four EICs can have different structures. For example, one EIC may include one or more HBMs along an AMS block, while another EIC may include one or more processors and an AMS block. Additionally, an EIC can include a combination of HBMs, processors and an AMS block. Another configuration may include an HBM, a high-density memory device (HDR), and an AMS block.

At step 1108, the second surface of the PIC is attached onto a first surface of the substrate such that the array of grating couplers is adjacent to the transparent region of the substrate. The PIC can be attached to the substrate by various bonding techniques, e.g., direct bonding, adhesive bonding, solder bumps, micro-bumps, copper pillars, or bonding pads. In some examples, the PIC is bonded to the substrate using bumps, and the bumpers are arranged outside the transparent region of the substrate to prevent disruption of optical signals. The method 1100 can further include underfilling the space between the bumps with an optically transparent material e.g., silicone encapsulant, epoxy resin, etc.) to enhance mechanical strength of the attachment.

At step 1110, the four EICs are flip-chip bonded onto the first surface of the PIC such that the AMS block of each EIC overlaps a respective active region of the four active regions of the PIC. Flip-chip bonding can involve depositing solder bumps on contact pads of the EIC, flipping it upside down, and aligning the contact pads of the EIC with corresponding pads on the PIC. The combined structure can then be heated to reflow the solder bumps, thereby forming electrical connections between the AMS block and the respective active region.

At step 1112, EICs and the PIC are encapsulated onto the substrate by using a molding compound. Encapsulating the EICs and PIC can involve applying a molding compound (e.g., epoxy resin, or silicone) over the EICs and PIC to shield them from environment. This process can be done through molding, or dispensing. Once encapsulated, the assembly can be cured to harden the material. As the EIC and the grating couplers are on the opposite sides of the PIC, the molding compound can underfill the space between the EIC and PIC without interfering the optical coupling between the grating couplers and the FAU.

At step 1114, a FAU is attached to a second surface of the substrate to direct optical signals to and receive optical signals from the array of grating couplers through the transparent region of the substrate. Therefore, the PIC and the FAU are on opposite sides of the substrate, respectively. Attaching the FAU onto the substrate involves aligning the FAU with the array of grating couplers (e.g., by pre-defined alignment marks), apply an optically transparent material at the interface and then cure the material. Attaching FAU onto the substrate can also involve mechanically plugging connectors of the FAU into corresponding receptacle of the substrate. In some examples, the FAU is attached at or near a geometric center of the second surface of the PIC (e.g., within a distance of 0.5 mm or less, 1 mm or less, or 2 mm or less,). The FAU can be attached to the substrate either before or after the encapsulation of the EICs and PIC. One or more specific implementations of the present disclosure are described herein. These described implementations are examples of the presently disclosed techniques. Additionally, to provide a concise description of these implementations, not all features of an actual implementation may be described in the specification. It should be appreciated that in the development of any such actual implementation, as in any engineering or design project, numerous implementation-specific decisions will be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

The described compute and memory nodes and fabric of communication links provide a distributed data processing environment, which may be referred to as a fabric-based environment, on which programs can be run. A compute node or memory node in such an environment will generally have installed on it a software stack that runs on one or more processors of the node to provide an operating environment, which may be referred to as a layer, on which program software deployed to the node can run.

The compute and memory nodes of a particular environment can be homogeneous, i.e., all the compute nodes are basically the same and all the memory nodes are basically the same, or they can be heterogeneous.

A compute node has one or more processors that can perform data processing operations, e.g., by executing program instructions, by performing operations implemented in hardware or firmware, by routing a data packet through the electrical interface, or otherwise. The processors can include, for example, CPUs, accelerators of various kinds, e.g., GPUs (graphics processing units), TPUs (tensor processing units), DPUs (data processing units), or programmed FPGAs (field-programmable gate arrays) or other special purpose ASICs (application specific integrated circuits), or by a combination of two or more of them.

A compute node generally has or is directly connected electrically to local memory, e.g., HBM, DDR, L1 and L2 caches, registers and the like.

A memory node, while it may have processors to run software and may have other characteristics of a compute node, has as its primary purpose in a fabric-based environment the purpose of providing access to data, specifically, for example, for use by compute processes running on compute nodes, and to enable other nodes to read and write data over photonic channels connecting the memory node to the other nodes. The memory devices a memory node has for storing data can be of one or more types. They are connected through respective memory controllers, message routers, and photonic interfaces through which other nodes read and write data by sending messages to ports implemented on the memory node.

Compute and memory nodes can have memory devices of one or more kinds, including, for example, flash memory, read-only memory, random-access memory (RAM), static RAM, dynamic RAM (DRAM), synchronous DRAM (SDRAM), double data rate (DDR) based DRAM, or high bandwidth memory (HBM) memory, or a combination of two or more of them.

Unidirectional photonic links have a photonic transmitter at one end and a photonic receiver at the other end linked by an optical waveguide, e.g., a semiconductor waveguide and/or an optical fiber.

Generally, a photonic channel used in a fabric-based environment is a bidirectional photonic channel, which has at least two unidirectional photonic links that transmit in opposite directions, providing, for example, for the transmission of messages in one direction and acknowledgements in the other.

In some implementations, the nodes of a fabric-based environment include routers to route data from one node, directly or through intermediary nodes, to another. Generally, data is transferred in messages over photonic or electrical channels in response to programs executing on the nodes or to operations of memory controllers or similar devices, for example. Such messages can be sent point-to-point, when the two nodes have links directly connect them, or through routers on one or more intermediary nodes that route messages according to addressing data that is part of the messages.

In some implementations, a compute node will have multiple ports, electrical or photonic or both, each directly connected by a link or channel, e.g., bidirectional channel, to a respective other node; and the messages sent by the compute node will be routed to the messages' target nodes by a router on the compute node that directs the messages to the appropriate port on the compute node. When a data message is received over a port, the router on the receiving node will examine the message header to determine the destination node in the fabric, either the node itself or another node, and process the message accordingly.

The addressing of messages through the fabric-based environment can be implemented in a variety of ways. In some implementations, multiple methods are implemented in the same fabric-based environment. In some addressing methods, messages carry the actual address of the message destination, and routers in the fabric implement what in effect are routing tables to transmit messages toward their destination addresses. In some implementations, the routing tables are updated dynamically in response to information about device failures or losses of connections, for example. In other addressing methods, messages are routed by relative addresses, i.e., addresses expressed as directional steps from the current node. Modeling nodes as points on a 2D, 3D, or higher dimensional grid, a target destination can be represented in a message header as a number of steps, which may be positive, negative, or zero, in each of the dimensions. When a message has been transmitted, the receiving node can update the message header of the message to account for the steps taken by the message from the sender in each dimension, with the result that the message header now contains a relative address relative to the receiving node. In other addressing methods, a combination of direct and relative addresses is used.

Memory nodes can be interconnected by photonic links, e.g., in the form of bidirectional photonic channels, to form a memory fabric. The memory fabric can be part of a server and generally includes multiple nodes in one or more packages. A package can include hundreds of nodes extending in multiple dimensions. A fabric made up of multiple packages can have hundreds of thousands of nodes or more, connected by photonic channels in a 2D, 3D, or higher dimensional memory fabric when the nodes have a sufficient number of photonic ports.

Generally, a fabric-based environment is implemented using packages of nodes. A package, sometimes called a System in Package (SiP), can include multiple nodes that are interconnected potentially both at an electrical layer of the package and on an interconnection substrate, e.g., a PIC, and which can be enclosed in a single casing. Each of the nodes in a package can have electrical connections, photonic connections, or both to other nodes within the package. Connections within a package are referred to as intra-chip connections, with the substrate being considered a chip. Connections between nodes in different packages are referred to as inter-chip connections.

In an environment with multiple packages, some or all of the nodes in one package have inter-chip photonic connections to nodes in one or more other packages. Generally, these inter-chip photonic connections are made by bidirectional photonic channels.

Generally, a program that runs on a fabric-based environment will be made up of program modules, each constructed to run on one of the nodes of the environment. Generally, each module includes instructions to invoke the services of the software stack on which it is running or of the underlying physical devices of the node, to load and store data, locally or remotely, to perform computing and control operations, and to communicate and coordinate with other modules of the program running on the same node or on other nodes on which the program has also been deployed.

Each of the one or more modules that make up a program can be coded separately for a respective particular kind of node. Or a large program can be broken up automatically, e.g., by a compiler, into separately deployable components to run on the nodes of a fabric-based environment. The environment and the resources available in its nodes and the characteristics of its connections, are described by a physical topology, to define, for example, the target for which the compiler is generating executable code.

A program or the modules of a program can generally be programmed using any suitable procedural, interpreted, or declarative language, or combinations of them, from which executable or interpretable code is automatically generated, e.g., by a compiler, to run on some run-time environment, for example, on some node hardware or some software layer or layers installed on the hardware.

A physical topology generally describes the locations of the nodes, any intra-chip connections and inter-chip connections each node has to other nodes. In some fabric-based environments, nodes are implemented in packages, and the location of a node may also include the package in which it is found. A physical topology may be stored in a topology file that defines an environment for a compiler or for deployment management software.

Program modules and components of the software stack will generally be deployed to nodes through electrical links from a control computer, which may be one of the nodes of the fabric-based environment programmed to perform this function, or which may be a separate control computer. These links can be direct or indirect, and may be provided by an electrical bus, e.g., a PCIe (Peripheral Component Interconnect Express) bus. In some implementations, the photonic links of the fabric-based environment may also be used to deploy modules and components to nodes.

Executable code can be deployed to nodes directly, or, for example, in containers which can be managed by a container management or orchestration system.

A fabric-based environment will generally include one or more nodes that are connected, or can be connected dynamically, to devices external to the fabric. External devices can include devices, for example, to provide human interaction for programs running on the fabric, or to provide data to, or to receive results from, such programs.

The fabric-based environment can be or be part of a general computing environment for executing programs. The computing environment can include or be associated with a compilation environment. The compilation environment takes a program input, e.g., an input machine learning model, and transforms it into machine-readable form by executing a compiler and a code generator. An input machine learning model can be provided in the form of a TensorFlow model, for example.

The application code generated by the compiler and code generator is, in some implementations, provided to a runtime environment running on the nodes of the computing environment. The runtime environment provides services to the running application code on the computing environment. In some implementations, the nodes of the computing environment include firmware that performs hardware-related operations, e.g., monitoring and driving hardware components of the computing environment, used by the runtime environment and the application code.

The application and runtime environment run on the compute nodes and use, if and as requested by the application, the resources of the fabric-based environment, including, for example, the compute nodes, memory nodes, memory devices, links and channels, routers, and ports.

To the extent this specification uses the term “configured to” in connection with systems, apparatus, and computer program components. That a system is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed, perform the operations or actions. That special-purpose circuitry is configured to perform particular operations or actions means that the circuitry circuit elements that, when put into operation, perform the operations or actions.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one implementation” or “an implementation” of the present disclosure are not intended to be interpreted as excluding the existence of additional implementations that also incorporate the recited features. For example, any element described in relation to an implementation herein may be combinable with any element of any other implementation described herein. Numbers, percentages, ratios, or other values stated herein are intended to include that value, and also other values that are “about” or “approximately” the stated value, as would be appreciated by one of ordinary skill in the art encompassed by implementations of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to implementations disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the implementations that fall within the meaning and scope of the claims are to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described implementations and implementations are to be considered illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A circuit package, comprising:
a substrate comprising a transparent region positioned to provide an optical path through the substrate from a first surface of the substrate to a second surface of the substrate opposite to the first surface of the substrate;
a photonic integrated circuit (PIC) attached to the first surface of the substrate, the PIC comprising:
four active regions spaced apart from each other, each active region comprising at least one optical modulator and at least one photodiode;
an optical interface adjacent to the transparent region of the substrate; and
a plurality of photonic paths connecting the optical interface to the four active regions, each of the plurality of photonic paths comprising one or more waveguides,
a fiber array unit (FAU) attached to the second surface of the substrate, the FAU being configured to direct optical signals to and receive optical signals from the optical interface through the transparent region of the substrate; and
four electronic integrated circuits (EICs) each attached to the first surface of the PIC, each EIC comprising an analog-mixed signal (AMS) block electrically coupled to a respective one of the four active regions of the PIC via electrical contacts on the first surface of the PIC,
wherein, for each of the EICs, the AMS block is located 2 mm or more from a nearest edge of the EIC.

2. The circuit package of claim 1, wherein each of the four active regions of the PIC is located at or near a respective edge of the PIC.

3. The circuit package of claim 1, wherein each of the four active regions of the PIC is located at or near a respective corner of the PIC.

4. The circuit package of claim 1, wherein the AMS block of each of the four EICs overlaps the respective active region of the four active regions in the PIC.

5. The circuit package of claim 1, wherein each of the four EICs extends beyond corresponding edges of the PIC.

6. The circuit package of claim 1, wherein the optical interface is located at or near a geometric center of the PIC.

7. The circuit package of claim 1, wherein the FAU is attached at or near a geometric center of the PIC.

8. The circuit package of claim 1, wherein the substrate comprises at least one of glass or optically transparent silicon.

9. The circuit package of claim 1, wherein the substrate comprises an interconnection region that includes at least one via, the at least one via is configured to supply power to the EIC, and the transparent region of the substrate is free of vias.

10. The circuit package of claim 9, wherein both the transparent region and the interconnection region comprise glass.

11. The circuit package of claim 1, wherein the substrate is a single layer of glass.

12. The circuit package of claim 1, wherein the substrate is a multilayer substrate, the transparent region extends through the multilayer substrate, and a layer of the multilayer substrate comprises an electrical connection configured to supply power to the EIC and PIC.

13. The circuit package of claim 1, further comprising molding compound at least partially encapsulating the EIC and the PIC.

14. The circuit package of claim 1, wherein the AMS block comprises at least one driver and at least one transimpedance amplifier (TIA), the at least one driver of the EIC being electrically coupled to the at least one optical modulator of the PIC, and the at least one TIA of the EIC being electrically coupled to the at least one photodiode of the PIC.

15. The circuit package of claim 1, further comprising a heat spreader element overlying the EIC.

16. The circuit package of claim 15, wherein the heat spreader element directly contacts the EIC.

17. The circuit package of claim 1, wherein the optical interface comprises an array of grating couplers.

18. A method, comprising:
providing a substrate comprising a transparent region;
providing a photonic integrated circuit (PIC) comprising
four active regions at a first surface of the PIC, the four active regions spaced apart from each other; and
an optical interface at a second surface of the PIC;
providing four electronic integrated circuits (EICs) each comprising an analog-mixed signal (AMS) block that is located 2 mm or more from a nearest edge of the respective EIC;
attaching the second surface of the PIC onto a first surface of the substrate such that the optical interface is adjacent to the transparent region of the substrate;
flip-chip bonding the four EICs onto the first surface of the PIC such that the AMS block of each EIC overlaps a respective active region of the four active regions of the PIC; and
encapsulating the EICs and the PIC onto the substrate.

19. The method of claim 18, comprising:
attaching a fiber array unit (FAU) to a second surface of the substrate to direct optical signals to and receive optical signals from the optical interface through the transparent region of the substrate.

20. The method of claim 18, wherein providing the PIC comprises:
providing the PIC that is formed using a single reticle.

21. The method of claim 18, wherein the substrate comprises at least one of glass or optically transparent silicon.

22. The method of claim 19, wherein attaching the FAU to the substrate comprises attaching the FAU at or near a geometric center of the second surface of the PIC.

23. The method of claim 18, wherein the optical interface comprises an array of grating couplers.
